(19) United States
(12) Patent Application Publication
(10) Pub. No.: US 2009/0147456 A1
(43) Pub. Date: Jun. 11, 2009

(54) Printed circuit board with multi layer ceramic capacitor and flat panel display device using the same

(76) Inventors: Sang-Uk Kim, Suwon-si (KR); Shawn Kim, Suwon-si (KR); Seong-Woock Hwang, Suwon-si (KR); In-Young Cho, Suwon-si (KR); Jeong-Min Park, Suwon-si (KR)

Correspondence Address: ROBERT E. BUSHNELL & LAW FIRM, 2029 K STREET NW, SUITE 600, WASHINGTON, DC, 20006-1004, US

(21) Appl. No.: 12/222,516

(22) Filed: Aug. 11, 2008

(30) Foreign Application Priority Data
Dec. 5, 2007 (KR) 10-2007-0125543

(51) Int. Cl. G06F 1/16; H05K 7/00; H05K 7/02

(52) U.S. Cl. 361/679.21; 361/728; 361/811

(57) ABSTRACT

A printed circuit board has an opening, and a multi-layer ceramic capacitor is disposed inside the opening and is coupled to the printed circuit board. The multi layer ceramic capacitor is coupled to the printed circuit board in a manner that a center of gravity of the multi-layer ceramic capacitor is at substantially the same level as a center of gravity of the printed circuit board.

### CLAIM OF PRIORITY

This application makes reference to, incorporates the same herein, and claims all benefits accruing under 35 U.S.C. §119 from an application for Printed Circuit Board with Multi Layer Ceramic Capacitor and Flat Panel Display Device Using the Same earlier filed in the Korean Intellectual Property Office on 5 Dec. 2007 and there duly assigned Serial No. 10-2007-0125543.

### BACKGROUND OF THE INVENTION

1. Field of the Invention

The present invention relates to a printed circuit board with a multi-layer ceramic capacitor and a flat panel display device using the same.

2. Description of the Related Art

A multi-layer ceramic capacitor (MLCC) is a chip type of capacitor wherein dielectric layers and electrode plates are configured of a multi-layer in a small thin film. It has been usefully used in a flat panel display device and the like since it is manufactured in a small size and has good temperature and frequency characteristics. The multi-layer ceramic capacitor is generally mounted on a surface of a printed circuit board so that it is built in the flat panel display device and the like.

However, since the multi-layer ceramic capacitor includes dielectric layers, it causes vibration driven by mechanical energy due to mechanical deformation caused by a characteristic of a dielectric layer material when electricity is applied to the multi-layer ceramic capacitor. As a result, it has a problem in that the printed circuit board vibrates, making it possible to cause noise. In other words, the multi-layer ceramic capacitor causes mechanical noise due to a piezoelectric deformation phenomenon caused by the characteristic of the dielectric layer material. The mechanical noise may inconvenience a user.

### SUMMARY OF THE INVENTION

It is an object of the present invention to provide a printed circuit board with a multi-layer ceramic capacitor and a flat panel display device using the same, which are capable of reducing vibration noise caused by a piezoelectric deformation phenomenon of the multi-layer ceramic capacitor.

In order to accomplish the object, a first aspect of the present invention provides a printed circuit board module that includes a printed circuit board having an opening, and a multi-layer ceramic capacitor disposed inside the opening and coupled to the printed circuit board.

The multi layer ceramic capacitor may be coupled to the printed circuit board in a manner that a center of gravity of the multi-layer ceramic capacitor is at substantially the same level as a center of gravity of the printed circuit board. The multi-layer ceramic capacitor may be fixedly coupled to the printed circuit board with a coupling material that connects the multi-layer ceramic capacitor to an edge of the opening.

A second aspect of the present invention provides a flat panel display device including a display panel for displaying an image and a printed circuit board for driving the display panel, and a multi-layer ceramic capacitor. The printed circuit board has an opening, and the multi-layer ceramic capacitor is disposed inside the opening and is coupled to the printed circuit board.

The multi layer ceramic capacitor may be coupled to the printed circuit board in a manner that a center of gravity of the multi-layer ceramic capacitor is at substantially the same level as a center of gravity of the printed circuit board. The multi-layer ceramic capacitor may be fixedly coupled to the printed circuit board with a coupling material that connects the multi-layer ceramic capacitor to an edge of the opening.

With the present invention, a vibration of the printed circuit board due to a piezoelectric deformation phenomenon of the multi layer ceramic capacitor is prevented by mounting the multi layer ceramic capacitor into the opening part of the printed circuit board as well as allowing the center of gravity of the multi layer ceramic capacitor and the center of gravity of the printed circuit board to be positioned at the same level (or height), making it possible to reduce noise.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings in which like reference symbols indicate the same or similar components, wherein:

FIG. 1 is a perspective view showing a multi-layer ceramic capacitor;

FIG. 2 is a view showing a deformation in a multi-layer ceramic capacitor when electricity is applied to the multi-layer ceramic capacitor;

FIG. 3 is a view showing a generation of vibration when electricity is applied to the multi-layer ceramic capacitor mounted on a surface of a printed circuit board;

FIG. 4 is an exploded perspective view showing a multi-layer ceramic capacitor according to an embodiment of the present invention and a printed circuit board with such a multi-layer ceramic capacitor;

FIG. 5 is a perspective view of a printed circuit board module that includes the multi-layer ceramic capacitor and the printed circuit board shown in FIG. 4;

FIG. 6 is a cross-sectional view showing a cross section taken along a line I-I′ in FIG. 5; and

FIG. 7 is a perspective view showing a flat panel display device adopting a printed circuit board with the multi-layer ceramic capacitor according to the present invention.

### DETAILED DESCRIPTION OF THE INVENTION

Hereinafter, certain exemplary embodiments according to the present invention will be described with reference to the accompanying drawings. Here, when a first element is described as being coupled to a second element, the first element may be not only directly coupled to the second element but may also be indirectly coupled to the second element via a third element. Further, some of the elements that are not essential to the complete understanding of the invention are omitted for clarity. Also, like reference numerals refer to like elements throughout.

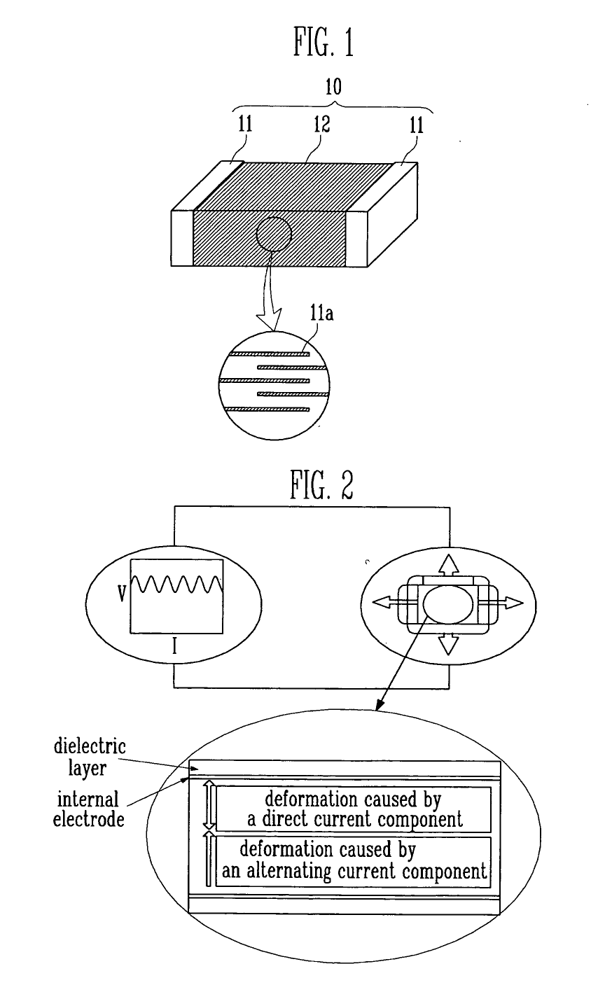

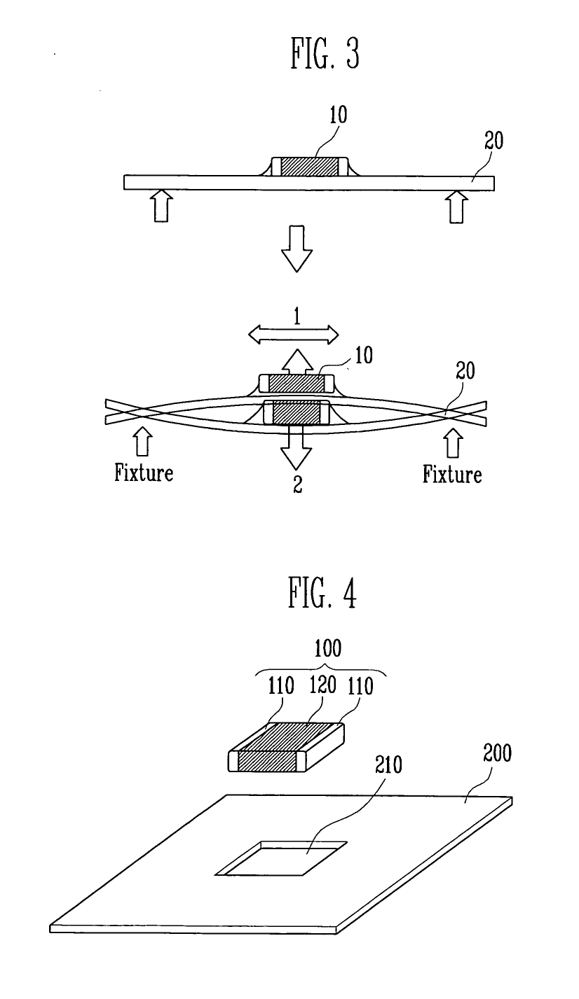

FIG. 1 is a perspective view showing a multi-layer ceramic capacitor. FIG. 2 is a view showing a deformation in a multi-layer ceramic capacitor when electricity is applied to the multi-layer ceramic capacitor and FIG. 3 is a view showing a generation of vibration when electricity is applied to the multi-layer ceramic capacitor mounted on a surface of a printed circuit board.

Referring to FIGS. 1 to 3, a multi-layer ceramic capacitor 10 includes a ceramic body 12 positioned between electrode plates 11 of both ends thereof. The ceramic body 12 includes a plurality of internal electrodes 11a and dielectric layers, each of which is disposed between two of the internal electrodes. The internal electrodes and the dielectric layers are configured of a multiple layers in a small thin film.

When the multi-layer ceramic capacitor 10 is supplied with, for example, a direct current and/or alternating current power as shown in FIG. 2, a mechanical deformation is produced in an area of the dielectric layer which is supplied with the current power.

More specifically, when the direct current power is supplied to the multi-layer ceramic capacitor 10, the dielectric layers configured of the multi-layer within the ceramic body 12 are expanded in a direction in which electric field corresponding to the direct current component is applied. As a result, the mechanical deformation in the dielectric layer is caused.

Also, when the alternating current power is supplied to the multi-layer ceramic capacitor 10, the dielectric layers repeats expansion and shrinkage according to the magnitude of the alternating current power. If alternating current power and direct current power are applied at the same time, the dielectric layers expand according to the direct current component and also repeats expansion and shrinkage according to the alternating current component. Therefore in any case, mechanical deformation or vibration is induced in the dielectric layers.

In view of the characteristics of dielectric, a piezoelectric deformation can be induced in a direction parallel and/or perpendicular to a direction of an applied electric field, when electricity is applied thereto. The mechanical deformation can be more induced in a direction perpendicular to the surface of the internal electrodes 11a and the dielectric layers of the ceramic body 12. Therefore, in the case that the internal electrodes are arranged parallel to the surface of the printed circuit board as shown in FIGS. 1 and 3, the mechanical deformation is to be more produced in a vertical direction that is perpendicular to the surface of the printed circuit board 20.

When the multi-layer ceramic capacitor 10 is mounted on the surface of the printed circuit board 20 as shown in FIG. 3, a relatively small amount of the mechanical deformation of the multi-layer ceramic capacitor 10 is induced in a horizontal direction that is parallel to the wider surface of the printed circuit board 20 (a direction ‘1’ in FIG. 3), because the multi-layer ceramic capacitor 10 is fixed by a soldering or the like on the printed circuit board 20 and the wider surface of the printed circuit board 20 is less affected by the mechanical deformation of the multi-layer ceramic capacitor 10. Therefore, movement in left and right directions (a direction in ‘1’ in FIG. 3) on the printed circuit board 20 may be relatively little in magnitude and weak in strength.

On the contrary, the mechanical deformation of the multi-layer ceramic capacitor 10 is relatively large in a vertical direction (a direction in ‘2’ in FIG. 3) that is perpendicular to the surface of the printed circuit board 20. Therefore, the printed circuit board 20 vibrates more strongly in the vertical direction, generating noise. As the center of gravity of the multi-layer ceramic capacitor 10 and the center of gravity of the printed circuit board 20 deviate from each other, the printed circuit board 20 can partially vibrate in any direction, generating more noise.

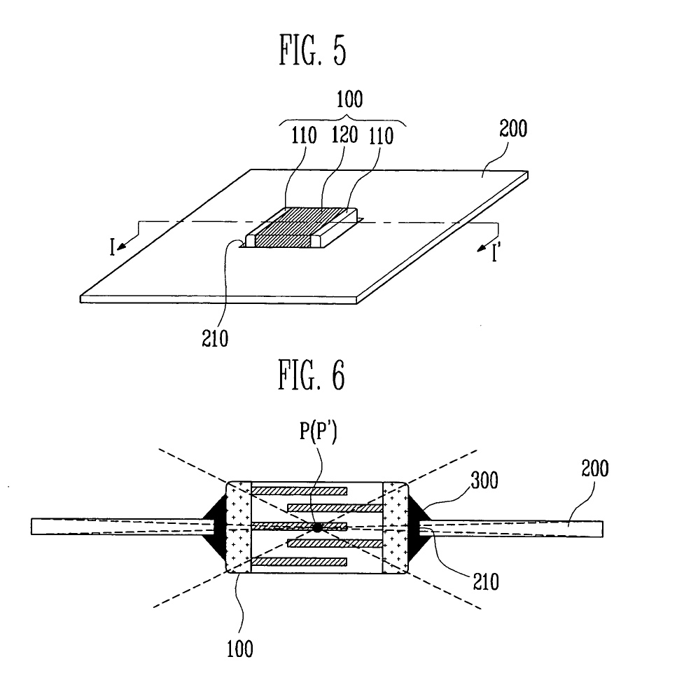

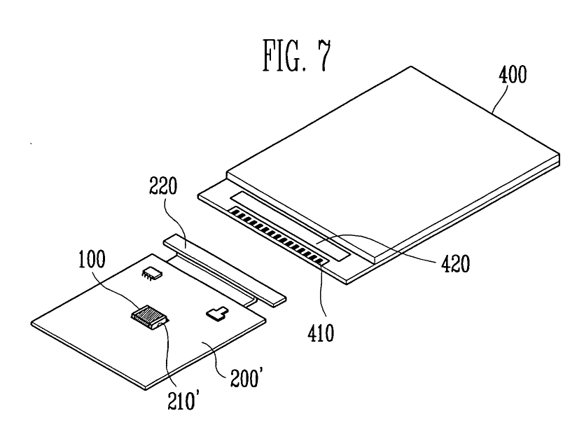

FIG. 4 is an exploded perspective view showing a multi-layer ceramic capacitor according to an embodiment of the present invention and a printed circuit board with such a multi-layer ceramic capacitor. FIG. 5 is a perspective view of a printed circuit board module that includes the multi-layer ceramic capacitor and the printed circuit board shown in FIG. 4, and FIG. 6 is a cross-sectional view showing a cross section taken along a line I-I′ in FIG. 5.

Referring to FIGS. 4 to 6, a multi-layer ceramic capacitor 100 configured of a ceramic body 120 positioned between electrode plates 110 of both ends thereof is inserted into an opening part 210 of a printed circuit board 200.

More specifically, a portion of the printed circuit board 200 is formed with an opening part (or an opening) 210 into which the multi-layer ceramic capacitor 100 is inserted. The multi-layer ceramic capacitor 100 is disposed inside the opening part 210 and coupled to the printed circuit board 200 in a manner that its center of gravity (P) is positioned at substantially the same level (or height) as the center of gravity (P′) of the printed circuit board 200 as shown in FIG. 6. Herein, the level of the center of gravity of the printed circuit board is measured as a height from the ground while the surface of the printed circuit board is arranged parallel to the ground. Therefore, even though the level of the center of gravity of the multi-layer ceramic capacitor 100 is the same as the level of the center of gravity of the printed circuit board 200, the center of gravity of the multi-layer ceramic capacitor may not be at the same location as the center of gravity of the printed circuit board. In other words, the locations of the centers of gravity can be different while the levels of the centers of gravity are the same.

For example, in the case that the multi-layer ceramic capacitor 100 is inserted into the opening part 210 of the printed circuit board 200, if the multi-layer ceramic capacitor 100 is thicker than the printed circuit board 200, there are projection parts that protrude beyond the surfaces of the printed circuit board 200 as shown in FIG. 6. In order to maintain the center of gravity of the multi-layer ceramic capacitor 100 at substantially the same level as the center of gravity of the printed circuit board, the heights of each projection parts of the multi-layer ceramic capacitor 100 projected above and below the printed circuit board 200, respectively, can be the same.

A width of the opening part 210 of the printed circuit board 200 may be formed to correspond to a width of the multi-layer ceramic capacitor 100. And, the multi-layer ceramic capacitor 100 may be inserted into the opening part 210 by means of a press fit, and is then mounted to the printed circuit board 200 by means of a soldering or the like.

Also, the width of the opening part 210 is formed to be wider by a predetermined length as compared to that of the multi-layer ceramic capacitor 100, and after the multi-layer ceramic capacitor 100 is properly positioned at the opening part 210, for example, a center portion thereof, it may be coupled to the printed circuit board 200 by means of a soldering. In this case, in a step of positioning the multi-layer ceramic capacitor 100 at the opening part 210 and of performing the soldering thereon, a substrate fixture (not shown) or the like supporting the printed circuit board 200 is formed with grooves in which the multi-layer ceramic capacitor 100 is firmly seated so that the soldering can be performed. A coupling material 300 is formed between an edge of the opening part 210 and the multi-layer ceramic capacitor 100 by means of the soldering or the like. The coupling material can be a lead material, and can be formed by soldering.

As described above, in the present invention the multi-layer ceramic capacitor 100 is mounted into the opening part 210 of the printed circuit board 200 and the centers of gravity of the multi-layer ceramic capacitor 100 and the printed circuit board 200 are positioned at the same height so that the vibration of the printed circuit board 200 can be effectively prevented. As a result, the noise due to the vibration of the printed circuit board 200 can be removed.

FIG. 7 is a perspective view showing a flat panel display device adopting a printed circuit board with the multi-layer ceramic capacitor according to the present invention. Referring to FIG. 7, a flat panel display includes a display panel 400 and a printed circuit board 200′ for driving it.

The display panel 400 is to display an image and can be a flat display panel such as a liquid crystal display panel or an organic light emitting display panel, etc. Herein, one side of the display panel 400 is formed with a pad part 410 that is electrically coupled to a pad part 220 of the printed circuit board 200′ and receives a driving signal from the printed circuit board 200′. A driving integrated circuit 420 may be mounted to the one side of the display panel 400.

The printed circuit board 200′ includes various circuit elements for driving the display panel 400 and supplies a driving signal to the display panel 400 through the pad part 220.

Herein, an area of the printed circuit board 200′ is formed with an opening part 210′. The multi-layer ceramic capacitor 100 is mounted to the opening part 210′ so that its center of gravity is positioned at the same height as the center of gravity of the printed circuit board 200′.

The multi-layer ceramic capacitor 100 has a small size and has good temperature and frequency characteristics so that it is useful for the driving of the flat panel display device. Also, even when the piezoelectric deformation phenomenon of the multi-layer ceramic capacitor 100 is induced, the mechanical deformation thereof does not vibrate the printed circuit board 200′, making it possible to provide the flat panel display device without noise caused by the vibration of the printed circuit board.

While the present invention has been described in connection with certain exemplary embodiments, it is to be understood that the invention is not limited to the disclosed embodiments, but, on the contrary, is intended to cover various modifications and equivalent arrangements included within the spirit and scope of the appended claims, and equivalents thereof.

What is claimed is:

1. A printed circuit board module comprising:
a printed circuit board having an opening; and
a multi-layer ceramic capacitor disposed inside the opening and coupled to the printed circuit board.

2. The printed circuit board as claimed in claim 1, wherein the multi layer ceramic capacitor is coupled to the printed circuit board in a manner that a center of gravity of the multi-layer ceramic capacitor is at substantially the same level as a center of gravity of the printed circuit board.

3. The printed circuit board as claimed in claim 1, wherein the multi-layer ceramic capacitor is fixedly coupled to the printed circuit board with a coupling material that connects the multi-layer ceramic capacitor to an edge of the opening.

4. A flat panel display device including:
a display panel for displaying an image;
a printed circuit board for driving the display panel, the printed circuit board having an opening; and
a multi-layer ceramic capacitor disposed inside the opening and coupled to the printed circuit board.

5. The flat panel display device as claimed in claim 4, wherein the multi layer ceramic capacitor is coupled to the printed circuit board in a manner that a center of gravity of the multi-layer ceramic capacitor is at substantially the same level as a center of gravity of the printed circuit board.

6. The printed circuit board as claimed in claim 4, wherein the multi-layer ceramic capacity or is fixedly coupled to the printed circuit board with a coupling material that connects the multi-layer ceramic capacitor to an edge of the opening.
